(19) United States
(12) Patent Application Publication
(10) Pub. No.: US 2004/0072396 A1
(43) Pub. Date: Apr. 15, 2004

(54) Semiconductor electronic device and method of manufacturing thereof

(75) Inventors: Roberto Tiziani, Nerviano (IT); Loic Renard, Agrate Brianza (IT); Battista Vitali, Romano di Lombardia (IT)

Correspondence Address: GRAYBEAL JACKSON HALEY LLP, Suite 350, 155-108th Avenue N.E., Bellevue, WA, 98004-5973, US

(73) Assignee: STMicroelectronics S.r.I.

(21) Appl. No.: 10/449,749

(22) Filed: May 29, 2003

(30) Foreign Application Priority Data
May 29, 2002 (EP) 02425348.6

(51) Int. Cl. H01L 21/8238

(52) U.S. Cl. 438/200

(57) ABSTRACT

A semiconductor electronic device is disclosed, which includes a die of a semiconductor material and a holder connected electrically together by wire leads of copper, the semiconductor material die being formed with a plurality of contact pads; the device being characterized by having a welding stud bump of a metal material selected from a group comprising gold, palladium, and alloys thereof, formed on each contact pad in said plurality, each copper wire lead being welded with one end on a stud bump and with the other end to said holder. This electronic device is highly reliable and can be fabricated simply at a low cost.

### PRIORITY CLAIM

This application claims priority from European patent application No. 02425348.6, filed May 29, 2002, which is incorporated herein by reference.

### TECHNICAL FIELD

The present invention relates generally to an electronic device comprising a die of a semiconductor material that is wire-bonded either to a holder or an integrated circuit having electrically conductive regions.

In particular, the invention relates to an electronic device as above, wherein the semiconductor material die is connected to the holder or the integrated circuit by means of copper wire leads, and to a method of fabricating such a device.

### BACKGROUND

As is well known, a semiconductor electronic device, e.g. a power device, comprises a die of a semiconductor material that has a surface area of a few square millimeters and an electronic circuit integrated monolithically to it. The die is formed with a plurality of terminals, typically a plurality of surface-formed contact pads for electrical connection to a holder that is an integral part of the electronic device.

The contact pads of a semiconductor material die are typically made of aluminum or alloyed aluminum, as dictated by the manufacture and functionality of such devices.

The holder, known as the “lead frame”, may be any of several types, including ceramics substrates, PC boards, flexible circuits, and silicon-based substrates.

The combination of the die and its holder is “packaged”, i.e. is coated for heat and mechanical protection of the electronic device throughout its shelf and useful life. The coating is typically of plastic.

The electrical connection of the semiconductor material die to the holder can be established using a number of different techniques, most commonly a wire bonding technique. More particularly, each wire has one end welded to a contact pad on the semiconductor material die and the other end welded to a contact pad on a holder to which the die is to be connected.

In the fabrication of semiconductor electronic devices, it is known to use aluminum wires for these electrical connections, which are welded to the contact pads ultrasonically. High gauge aluminum wires (up to 500 microns in diameter), as are required in high-power electronic devices on account of the high working voltages and current densities that such devices involve, can be welded by this method.

However, the rate of installation of aluminum wire leads by thermal/sonic processes tends to be low (usually less than 2 wires per second), which is time-consuming. In addition, fairly expensive equipment must be available for installing the wires, which adds to manufacturing costs.

Also known is to connect the semiconductor material die electrically to its holder by means of gold wires, since gold bonds well to the aluminum pads.

Gold wires can be welded to the contact pads by a thermal/sonic process, i.e. by the concurrent application of heat and sonic energy. This technique results in a greatly improved rate of gold wire installation, compared with ultrasonic welding (usually raising it to above 10 wires per second), thereby making for more efficient overall processing time.

However, the thermal/sonic processes employed to establish connections by gold wires tend to raise the manufacturing cost of electronic devices due to the high cost of gold. Thus, the thermal/sonic methods are usually applied only to low-power electronic devices that can do with small-gauge gold wires (usually 75 microns or less in diameter). Manufacturing cost is no better than slightly improved by the higher rate of wire installation, and by the use of thermal/sonic equipment that is less expensive than ultrasonic equipment.

For example, one aluminum wire with a 254-micron diameter, which is the most widely used gauge in ultrasonic processes, would ensure the same connection strength as ten gold wires with a 75-micron diameter, but the use of gold wires would bring about a substantial increase in manufacturing cost.

To reduce manufacturing costs, a recent proposal provides for the use of copper rather than gold wires for connecting the semiconductor material die to its holder. Copper is less expensive than gold, and its resistivity is advantageously lower. In addition, copper wires can be welded to the contact pads using the same thermal/sonic processes as for gold wires, resulting in better installation rates and processing times.

On the other hand, copper is harder (110 Wickers) than gold (60 Wickers) or aluminum (40 Wickers), and makes bonding to the aluminum contact pads more difficult, since larger amounts of sonic energy must be delivered at higher temperatures.

In this circumstance, it is found that the increased energy requirements (both sonic and heat energy) of copper-wire welding may harm or crack the semiconductor material die in the pad area or the semiconductor material itself. Such damage or cracking is responsible for current and power leakages resulting in unreliable electronic devices. In the extreme, the conduction terminals (drain/source or emitter/source) of an electronic device may become shorted to each other.

Therefore, a need has arisen for a semiconductor electronic device comprising a die of a semiconductor material that is connected to the holder by copper wire leads, the device being low in manufacturing cost and having appropriate constructional and operational features to overcome the aforementioned shortcomings of the prior art.

### SUMMARY

One embodiment of the invention is a semiconductor electronic device, wherein a die of a semiconductor material and a holder are connected electrically to each other by wire leads of copper, the semiconductor material die being formed with a plurality of contact pads; characterized in that it has a welding stud bump of a metal material selected from a group comprising gold, palladium, and alloys thereof, formed on each contact pad in said plurality, each copper wire lead being welded with one end on a stud bump, and with the other end, to said holder.

In such an embodiment, each contact pad can be formed conventionally from aluminum or an aluminum alloy, on the semiconductor material die.

The welding stud bump can be formed conventionally by welding the metal material to a contact pad, preferably using a thermal/sonic welding process. Preferably, the welding stud bump is in the shape of an oblate sphere 10 to 50 microns high.

A preferred material for the stud bumps is gold or alloyed gold.

Each copper wire is welded by a conventional thermal/sonic technique with one end on the welding stud bump formed on a contact pad. This process usually provides for a copper ball to be formed by melting one end of the copper wire and then pressed onto the welding stud bump while heat is optionally applied to weld the ball and the stud bump together. Accordingly, the copper-wire end welded on the stud bump will typically take an oblate spherical shape.

It has been found that by having the stud bumps formed from the above-specified metals on the contact pads of the semiconductor-material die, the risk of cracking or harming the semiconductor material die as the copper wires are welded is unexpectedly attenuated. In practice, the metal material of the stud bump takes in most of the compression, vibration and/or thermal stresses produced by the wire-lead welding process, thereby preserving the contact pads and the semiconductor material of the die from crack failure or damage. However, stud bumps formed from metals other than the above-specified metals may also provide these advantages.

In this way, the proportion of rejects from faulty or unreliable electronic devices, or short-circuited devices, can be reduced substantially.

It should be noted in this respect that the manufacture of copper wire-bonded electronic devices exhibits a rather high percentage of rejects, approximately 50% of the output. But according to this embodiment of the invention, on the other hand, this percentage can advantageously be brought down to zero rejects.

This is achieved at low manufacturing costs, in virtually all cases lower than the costs involved in thermal/sonic methods where gold wires are used for the electrical connections. It should be noted in this respect that the added cost for the materials, such as gold and/or palladium, used in forming the welding stud bumps is quite trivial because such materials are only used in very small amounts.

It should be further noted that the stud bumps on the contact pads can be formed, and the copper wires welded to the stud bumps, using a thermal/sonic technique. This advantageously improves the rate of installation of copper wires and, hence, the time for manufacturing an electronic device according to an embodiment of this invention. Advantageously, this embodiment of the electronic-device fabricating process can be optimized and standardized using the same thermal/sonic technique to provide both the stud bumps and the copper wire connections, and using either a single apparatus or two apparatus in series within the production line.

Another embodiment of this invention relates to a method of fabricating a semiconductor electronic device comprising a die of a semiconductor material and a holder connected electrically together by copper wire leads, the semiconductor material die being formed with a plurality of contact pads, which method is characterized in that it comprises the steps of:

on each contact pad in said plurality, providing a welding stud bump formed from a metal material selected from a group comprising gold, palladium, and alloys thereof; and

welding one end of a copper wire on a stud bump and the other end to said holder.

Preferably, the step of providing the stud bump comprises welding said metal material to a respective contact pad by a thermal/sonic process. In this process, a wire of the stud bump material is fed through a capillary duct overlying the semiconductor material die, one wire end jutting out of the capillary duct is molten to form a ball of said material, and the ball is pressed onto the contact pad while ultrasonic vibratory energy and heat are applied through the capillary duct. After a predetermined compression period, the ball that has been pressed onto the contact pad is separated from the wire to leave on the pad a stud bump of substantially oblate spherical shape for later weld connection to the copper wire.

Preferably, the copper wire-welding is performed using a thermal/sonic technique.

### BRIEF DESCRIPTION OF THE DRAWING

Further advantages of such a semiconductor electronic device will be apparent from the following description of an embodiment thereof, given by way of non-limitative example with reference to the accompanying drawing.

FIG. 1 is a sectional view taken through a portion of a semiconductor electronic device according to an embodiment of the invention.

### DETAILED DESCRIPTION

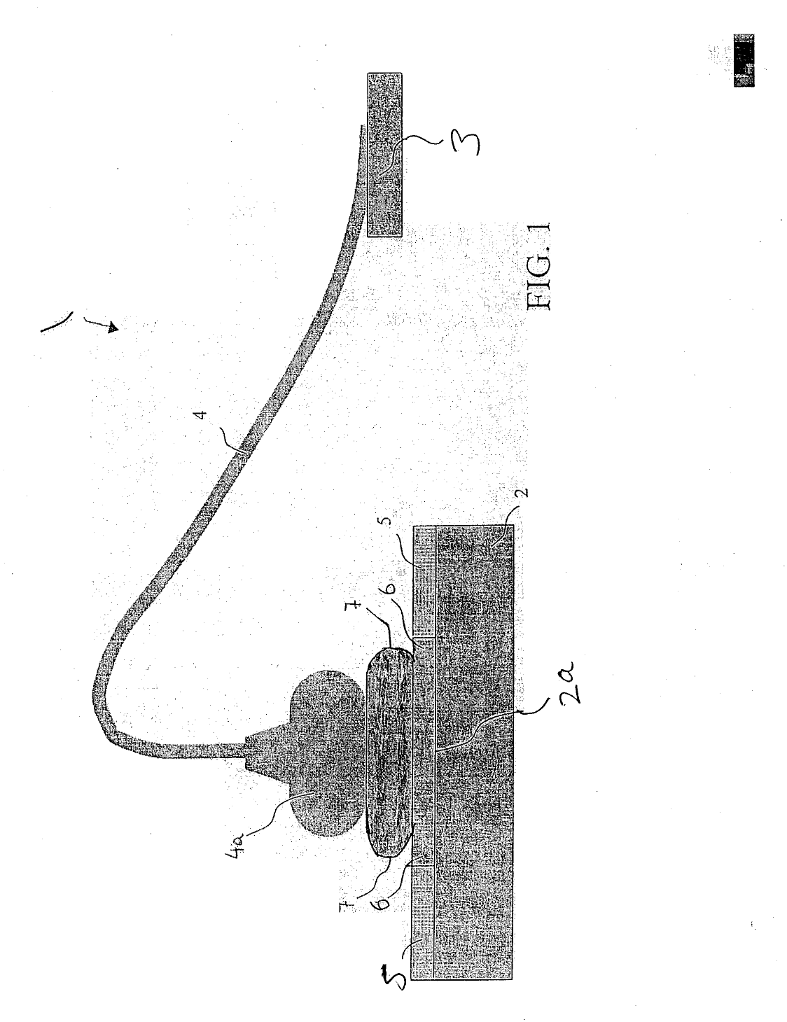

With reference to FIG. 1, a semiconductor electronic device according to an embodiment of the invention is generally shown at 1. The device 1 comprises a die 2 of a semiconductor material, which is connected electrically to a holder 3 by wire leads 4 of copper. One wire lead 4 is shown in FIG. 1 for simplicity. The die 2 comprises an integrated electronic circuit (not shown) and is coated with a layer 5 of an insulative material. This insulative material layer 5 is apertured to expose portions 2a of a surface of the die 2 where respective contact pads of aluminum are formed for electrically connecting the die 2 and holder 3 together. For simplicity, in FIG. 1 only a single portion 2a of the exposed surface of the die 2 is shown, on which a contact pad, generally shown at 6, is formed.

According to this embodiment of the invention, the electronic device 1 also has a welding stud bump 7 formed from gold (or any other suitable conductive material) with an oblate spherical shape, the bottom of the stud bump being welded to the contact pad 6 using a thermal/sonic technique.

One end 4a of the copper wire 4 is welded on the top of the stud bump 7 by a thermal/sonic process. In this process, the end 4a is given a substantially oblate spherical shape for improved strength of the bond to the stud bump 7 beneath.

The other end of the wire 4 is conductively attached to the holder 3 using a conventional technique.

Furthermore, the integrated circuit (IC) formed by the packaged die 2 and holder 3 can be any type of IC such as a memory or a processor. Moreoever, this IC can be incorporated into an electronic system such as a computer system.

From the foregoing it will be appreciated that, although specific embodiments of the invention have been described herein for purposes of illustration, various modifications may be made without deviating from the spirit and scope of the invention.

What is claimed is:

1. A semiconductor electronic device comprising a die of a semiconductor material and a holder connected electrically together by wire leads of copper, the semiconductor material die being formed with a plurality of contact pads; characterized in that it has a welding stud bump of a metal material selected from a group comprising gold, palladium, and alloys thereof, formed on each contact pad in said plurality, each copper wire lead being welded with one end on a stud bump and with the other end to said holder.

2. An electronic device according to claim 1, characterized in that each contact pad in said plurality is formed from aluminum or alloyed aluminum.

3. An electronic device according to claim 1, characterized in that the welding stud bump is formed from gold.

4. An electronic device according to claim 1, characterized in that the welding stud bump has a substantially oblate spherical shape and height of 10 to 50 microns.

5. An electronic device according to claim 1, characterized in that the end of the copper wire welded on the stud bump has a substantially oblate spherical shape.

6. A method of fabricating a semiconductor electronic device comprising a die of a semiconductor material and a holder connected electrically together by copper wire leads, the semiconductor material die being formed with a plurality of contact pads; characterized in that it comprises the steps of:
on each contact pad in said plurality, providing a welding stud bump formed from a metal material selected from a group comprising gold, palladium, and alloys thereof; and
welding one end of a copper wire on a stud bump and the other wire end to said holder.

7. A method according to claim 6, characterized in that the welding stud bump is formed by welding the metal material to the contact pad in a thermal/sonic process.

8. A method according to claim 6, characterized in that the end of the copper wire is welded on the stud bump using a thermal/sonic welding process.

9. An integrated circuit, comprising:
a substrate;
a conductive pad disposed on the substrate;
a conductive stud bump disposed on the pad; and
a conductive wire having a first end disposed on the stud bump.

10. The structure of claim 9 wherein the substrate comprises a semiconductor substrate.

11. The structure of claim 9 wherein the pad comprises aluminum.

12. The structure of claim 9 wherein the stud bump comprises gold.

13. The structure of claim 9 wherein the stud bump comprises palladium.

14. The structure of claim 9 wherein the stud bump is disk shaped.

15. The structure of claim 9 wherein the wire comprises copper.

16. The structure of claim 9 wherein the first end of the wire is disk shaped.

17. The structure of claim 9, further comprising an electronic device disposed in the substrate.

18. The structure of claim 9, further comprising:
a lead frame having a lead; and
wherein the wire comprises a second end attached to the lead.

19. An integrated circuit, comprising:
a semiconductor die that includes,
a conductive contact pad, and
a conductive stud bump disposed on the pad;
a lead frame that includes a lead; and
a conductive wire having a first end attached to the stud bump and having a second end attached to the lead.

20. The integrated circuit of claim 19 wherein the semiconductor die further includes an electronic device.

21. An electronic system, comprising:
an integrated circuit that includes,
a substrate,
a conductive pad disposed on the substrate,
a conductive stud bump disposed on the pad, and
a conductive wire having a first end disposed on the stud bump.

22. A method, comprising:
forming a conductive stud bump on a conductive pad that is disposed on a substrate; and
bonding a first end of a wire to the stud bump.

23. The method of claim 22 wherein forming the stud bump comprises welding a metal to the pad.

24. The method of claim 22 wherein forming the stud bump comprises thermally and sonically welding a metal to the pad.

25. The method of claim 22 wherein bonding the wire comprises welding the first end of the wire to the stud bump.

26. The method of claim 22 wherein bonding the wire comprises thermally and sonically welding the first end of the wire to the stud bump.

27. The method of claim 22, further comprising attaching a second end of the wire to a lead frame.
